(19) United States
(12) Patent Application Publication
(10) Pub. No.: US 2023/0159866 A1
(43) Pub. Date: May 25, 2023

(54) MICROELECTRONIC DEVICE CLEANING COMPOSITION

(71) Applicant: ENTEGRIS, INC., Billerica, MA (US)

(72) Inventors: Atanu K. Das, Southbury, CT (US); Daniela White, Ridgefield, CT (US); Michael L. White, Ridgefield, CT (US); Jun Liu, Newtown, CT (US); Aditya Dilip Verma, Gainesville, FL (US)

(21) Appl. No.: 17/991,251

(22) Filed: Nov. 21, 2022

Related U.S. Application Data
(60) Provisional application No. 63/282,385, filed on Nov. 23, 2021.
(60) Provisional application No. 63/307,885, filed on Feb. 8, 2022.

(51) Int. Cl. C11D 11/00; C11D 1/72; C11D 3/43; C11D 3/30; C11D 3/04; C11D 3/37; C11D 3/34; C11D 3/39; C11D 3/36; C11D 3/22; H01L 21/02

(52) U.S. Cl. CPC C11D 11/0047; C11D 1/721; C11D 3/43; C11D 3/30; C11D 3/044; C11D 3/3776; C11D 3/3454; C11D 3/3942; C11D 3/042; C11D 3/361; C11D 3/225; H01L 21/02057

(57) ABSTRACT

Provided are compositions and methods useful in the post-CMP cleaning of microelectronic devices, in particular, devices which contain one or more surfaces comprising hydrophobic carbon or SiC. In general, the compositions comprise a chelating agent; a water-miscible solvent; a reducing agent; and a pH adjustor, wherein the composition has a pH of about 2 to about 13.

### TECHNICAL FIELD

The invention generally relates to aqueous compositions for cleaning the surface of a microelectronic device substrate, such as for cleaning post-CMP residue from the surface of a microelectronic device substrate.

### BACKGROUND

Microelectronic device substrates are used for preparing integrated circuit devices. The microelectronic device substrate includes a base, such as a silicon wafer having a highly planar surface. Onto the planar surface of the base, by way of many multiples of selective placement and removal steps, regions of electronically-functional features are added. The features are made by selectively adding and removing electronically-functional materials that exhibit insulative, conductive, or semi-conductive properties. These electronically-functional materials are placed as desired by use of processing materials that include photoresist, chemical etchant, and slurries that contain abrasive particles and chemical materials that aid in processing the surface.

One feature of integrated circuits is an array of conductive “interconnects,” which are also referred to as “lines” and “vias.” As part of an integrated circuit, conductive interconnects function to conduct electric current among and between various other electronic features. Each interconnect is in the form of a line or thin film of conductive material that extends within and is defined (in shape and size) by openings formed in an insulative material, i.e., a dielectric material such as a dielectric material. The dielectric material acts as an insulator between the very-closely spaced interconnect structures, and between the interconnect structures and other electronic features of the integrated circuit.

The types of materials used to produce the interconnect and the dielectric structures must be selected to properly function as part of an integrated circuit that performs at high efficiency and high reliability. For example, the conductive material of an interconnect should be of a type that does not migrate (e.g., diffuse) excessively into an adjacent dielectric material over time and during use in the presence of a voltage between the materials; such migration of interconnect material into an adjacent dielectric material is often referred to as “electromigration.” At the same time, the combined interconnect and dielectric material structure must have sufficient integrity, including at an interface between these materials, to result in a low level of defects and a high level of performance reliability. For example, a strong bond must exist at the interface to prevent separation of the dielectric material from the interconnect material during use.

Interconnects have in the past been commonly made of aluminum or tungsten, and more recently are made of copper. Copper has an advantageously high conductivity relative to aluminum and tungsten. In addition, copper-based interconnects offer better resistance to electromigration as compared to aluminum, thereby improving the reliability of the integrated circuit over time. Still, copper ions can tend to diffuse into silicon dioxide (SiO₂) under sufficient electrical bias, and adhesion of copper to silicon dioxide and to other dielectric materials can be poor.

To prevent these negative interactions of copper with a dielectric material, recent integrated circuit structures have been designed to include a barrier layer between a copper interconnect structure and an adjacent dielectric material. Example barrier layers may be conductive materials or non-conductive materials, examples including tantalum (Ta), tantalum nitride (TaNₓ), tungsten (W), titanium (Ti), titanium nitride (TiN), ruthenium (Ru), cobalt (Co), molybdenum (Mo), rhenium (Rh), and alloys thereof.

Processes of placing the various features of microelectronic devices onto a substrate include selectively placing insulative materials (e.g., dielectric, etc.), semiconducting materials, metal materials (e.g., conductive lines and vias (i.e., interconnects), etc., onto a substrate surface. Selective placement and removal of these materials may involve the use of process compositions such as photoresist, etchant, CMP slurries that contain abrasive and chemical materials, and plasma, among others, in steps such as photoresist coating, etching (e.g., wet etching, plasma etching), chemical-mechanical processing (a.k.a., chemical-mechanical polishing, chemical-mechanical planarization, or simply “CMP”), and ashing (“plasma ashing”).

Chemical-mechanical processing is a process by which very small amounts (thicknesses) of material are precisely removed from a surface of a microelectronic device substrate to polish (or “planarize”) the surface in preparation for a subsequent layer of material to be applied onto the processed surface. Chemical-mechanical processing involves highly precise mechanical abrasion of a surface, coupled with controlled interactions of chemical materials, such as oxidation, reduction, or chelation of a material that is present at or removed from the surface. Often, one type of material at the substrate surface (e.g., metal overburden) is preferentially removed, with high selectivity, in comparison to a reduced degree of removal of one or more other materials that are also present at the surface (e.g., dielectric material).

A CMP process involves applying a “slurry” to the surface along with contacting the surface with a moving CMP pad. The “slurry” is a liquid composition that contains microabrasive particles that provide mechanical abrasion of the surface, along with chemical materials that interact chemically with materials of the surface to facilitate selective removal of certain material from the surface and, often, to inhibit removal of another surface material. The slurry is applied to the surface while the CMP pad contacts the surface with the desired amount of pressure and motion to facilitate the abrasive and chemical removal of select materials from the surface. The combination of the mechanical action of the pad and abrasive particles moving against the surface, along with the action of the chemical ingredients, achieves desired removal, planarization, and polishing of the surface with desired low levels of defects and residue. The CMP process should produce a highly planar, low-defect, low-residue surface to which a subsequent layer of a microelectronic device can be applied.

After a processing step (e.g., chemical-mechanic processing, etching, ashing, etc.), at least some amount of residue will be present at a surface of a substrate. Residue may include abrasive particles from a CMP slurry or other processing material; active chemical ingredients that are part of a CMP slurry (e.g., oxidizer, catalyst, inhibitor) or other processing composition (e.g., etchant); a reaction product or by-product of a processing material or ingredient thereof; a chemical etchant; photoresist polymer or other solid processing ingredient; etc. Any such residue must be removed by cleaning the surface before performing a subsequent step of a microelectronic device fabrication process, to avoid defects or other potential sources of reduced device performance or reliability

Certain methods and equipment commonly used for cleaning a surface of a microelectronic substrate, e.g., after an etching step, after a CMP step, or after another step used in fabricating a multi-layer microelectronic device, include those that involve a flow of cleaning solution over the surface in combination with megasonics, jetting, or brushing to remove residue and contaminants. Typical cleaning solutions include alkaline solutions, e.g., containing a suitable hydroxide compound along with other chemical materials that together remove residue from the surface by chemically interacting with the residue. The cleaning solution should be effective to remove a high percentage of residue from a surface, but also must be safe with respect to functional features of the substrate. A cleaning solution must not cause damage to those features. For example, a cleaning solution should not cause corrosion (i.e., oxidation) of a metal feature of a substrate, e.g., should not oxidize copper or cobalt metal features of a substrate that may be present as interconnect or barrier features.

New, useful, and improved cleaning compositions and specific ingredients are continually sought, especially for use with new microelectronic device structures. Additionally, it would be of interest to develop improved cleaning compositions which could also perform such a cleaning function in those microelectronic device structures which contain hydrophobic surfaces, such as hydrophobic carbon surfaces or SiC surfaces, as such surfaces tend to retain metal oxide post-CMP waste products.

### SUMMARY

In summary, the invention provides a composition comprising:
a. a chelating agent;
b. a water-miscible solvent;
c. a reducing agent; and
d. a pH adjustor,
   wherein the composition has a pH of about 2 to about 13.

In one embodiment, the pH of the composition is about 2 to about 5. In another embodiment, the composition further comprises a dispersant. In another embodiment, the composition further comprises a wetting agent. In another embodiment, the composition further comprises a fluoride source. The compositions of the invention are effective in the cleaning of post-CMP waste materials from microelectronic device substrates having hydrophobic surfaces, especially those possessing hydrophobic carbon surfaces. Furthermore, the compositions are also effective for removing post-CMP materials from substrates comprising SiC surfaces.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a composition comprising:
a. a chelating agent;
b. a water-miscible solvent;
c. a reducing agent; and
d. a pH adjustor,
   wherein the composition has a pH of about 2 to about 13.

In one embodiment, the pH of the composition is about 2 to about 5. In another embodiment, the composition further comprises a dispersant. In another embodiment, the composition further comprises a wetting agent. In another embodiment, the composition further comprises a fluoride source.

In one embodiment, the composition will be comprised of about 60 to 90 weight percent water, about 0.1 to about 20 weight percent of a chelating agent, about 0.1 to about 10 weight percent of a water-miscible solvent, about 0.1 to about 5 weight percent of a reducing agent; and an amount of acid or base necessary to achieve the desired pH.

In certain embodiments, the composition consists of or consists essentially of components a. through d. above, either with or without the aforementioned optional ingredients.

As used herein, unless otherwise specified, a composition or ingredient of a composition that is described as “consisting essentially of” one or more specified items refers to a composition or ingredient that is made up of only those specified items with not more than an insubstantial amount of other (additional) materials, e.g., contains only the specified items and not more than 5, 3, 2, 1, 0.5, 0.1, 0.05, or 0.01 weight percent additional ingredients based on the total weight of the composition or the ingredient. As used herein, a composition or ingredient of a composition that is described as “consisting of” one or more specified items refers to a composition or ingredient that is made up of only those specified items.

In the compositions of the invention, suitable chelating agents are chosen from phosphonates (e.g., 1-hydroxyethylidene-1,1-diphosphonic acid (HEDP), 1,5,9-triazacyclododecane-N,N′,N″-tris(methylenephosphonic acid) (DOTRP), 1,4,7,10-tetraazacyclododecane-N,N′,N″,N′″-tetrakis(methylenephosphonic acid) (DOTP), nitrilotris(methylene)triphosphonic acid, diethylenetriaminepentakis(methylenephosphonic acid) (DETAP), aminotri(methylenephosphonic acid), bis(hexamethylene)triamine pentamethylene phosphonic acid, 1,4,7-triazacyclononane-N,N′,N″-tris(methylenephosphonic acid (NOTP), hydroxyethyldiphosphonate, nitrilotris(methylene)phosphonic acid, 2-phosphono-butane-1,2,3,4-tetracarboxylic, carboxy ethyl phosphonic acid, aminoethyl phosphonic acid, glyphosate, ethylene diamine tetra(methylenephosphonic acid) phenylphosphonic acid, salts thereof, and derivatives thereof) and/or carboxylic acids (e.g., oxalic acid, succinnic acid, maleic acid, malic acid, malonic acid, adipic acid, phthalic acid, citric acid, sodium citrate, potassium citrate, ammonium citrate, tricarballylic acid, trimethylolpropionic acid, picolinic acid, dipicolinic acid, salicylic acid sulfosalicylic acid, sulfophthalic acid, Sulphosuccinic acid, Betaine, gluconic acid, tartaric acid, glucuronic acid, 2-carboxypyridine) and/or sulfonic acids such as TIRON (4,5-Dihydroxy-1,3-benzenedisulfonic acid disodium salt) or HEPES—2-[4(2-hydroxyethyl)piperazin-1-yl]ethanesulfonic acid. In certain embodiments, the chelating agent includes nitrilotris (methylene)triphosphonic acid and iminodiacetic acid. The amount of chelating agent(s) in the composition is in one embodiment, in a range from about 0.01 wt % to about 10 wt %, based on the total weight of the removal composition. Amino acids and chelating acids. In one embodiment, the chelating agent is 1-hydroxyethylidene-1,1-diphosphonic acid.

In the compositions of the invention, suitable water miscible solvents include alcohols, glycols, polyols, and glycol ethers. Examples include methanol, ethanol, isopropanol, butanol, and higher alcohols, C₂-C₄ diols and C₂-C₄ triols, tetrahydrofurfuryl alcohol, 3-chloro-1,2-propanediol, 3-chloro-1-propanethiol, 1-chloro-2-propanol, 2-chloro-1-propanol, 3-chloro-1-propanol, 3-bromo-1,2-propanediol, 1-bromo-2-propanol, 3-bromo-1-propanol, 3-iodo-1-propanol, 4-chloro-1-butanol, 2-chloroethanol), dichloromethane, chloroform, acetic acid, propionic acid, trifluoroacetic acid, tetrahydrofuran N-methylpyrrolidinone, cyclohexylpyrrolidinone, N-octylpyrrolidinone, N-phenylpyrrolidinone, methyldiethanolamine, methyl formate, dimethyl formamide, dimethylsulfoxide, tetramethylene sulfone, diethyl ether, phenoxy-2-propanol, propriophenone, ethyl lactate, ethyl acetate, ethyl benzoate, acetonitrile, acetone, ethylene glycol, propylene glycol, 1,3-propanediol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether, tripropylene glycol n-propyl ether, propylene glycol n-butyl ether, dipropylene glycol n-butyl ether, tripropylene glycol n-butyl ether, propylene glycol phenyl ether, ethylene glycol monophenyl ether, diethylene glycol monophenyl ether hexaethylene glycol monophenylether, dipropylene glycol methyl ether acetate, tetraethylene glycol dimethyl ether dibasic ester, glycerine carbonate, sorbitol, glycerol, and dimethylsulfoxide.

In certain embodiments, the water-miscible solvent is chosen from triethylene glycol monobutyl ether and dimethylsulfoxide.

In the compositions of the invention, suitable reducing agents are chosen from hydrophosphorous acid (H₃PO₂), ascorbic acid, L(+)-ascorbic acid, isoascorbic acid, ascorbic acid derivatives, DEHA (diethylhydroxylamine), reducing sugar (galactose) and combinations thereof. Additionally, phosphorous acid, sulfurous acid, ammonium and potassium thiosulfate, xylose, sorbitol. N-aminomorpholine, N-aminopiperazine, hydroquinone, catechol, tetrahydrofulvalene, N,N-Dimethylanilinebenzylamine, hydroxylamine and other sulfur based reducing agents may be utilized. In certain instances, in the presence of certain metals, such as manganese and iron, hydrogen peroxide also can function as a reducing agent. In certain embodiments, the reducing agent is chosen from diethylhydroxylamine, ascorbic acid, and hydrogen peroxide. In other embodiments, the reducing agent is chosen from ammonium sulfite, potassium sulfite, sodium sulfite, dopamine HCl, phosphorous acid, phosphinic acid, hypophosphorous acid, potassium metabisulfite, sodium metabisulfite, ammonium metabisulfite, potassium pyruvate, sodium pyruvate, ammonium pyruvate, formic acid, sodium formate, potassium formate, ammonium formate, dopamine, sulfur dioxide solution, and any combination thereof. In certain embodiments, the reducing agent is chosen from diethylydroxylamine and hydrogen peroxide. In various embodiments, the amount of reducing agent in the composition is in the range of from about 0.0001 wt % to about 5 wt % based on the total weight of the cleaning composition.

In some embodiments, the compositions of the invention further comprise a dispersant. Suitable dispersants include alkanolamines. Examples of alkanolamines include, without limitation, alkanolamines such as aminoethylethanolamine, N-methylaminoethanol, aminoethoxyethanol, dimethylaminoethoxyethanol, diethanolamine, N-methyldiethanolamine, monoethanolamine (MEA), triethanolamine (TEA), isopropanolamine, diisopropanolamine, aminopropyldiethanolamine, N,N-dimethylpropanolamine, N-methylpropanolamine, 1-amino-2-propanol, 2-amino-1-butanol, isobutanolamine, triethylenediamine, other C₁-C₈ alkanolamines and combinations thereof. When the amine includes the alkylether component, the amine may be considered an alkoxylamine, e.g., 1-methoxy-2-aminoethane, or morpholine or morpholine xoide

In one embodiment, the alkanolamine dispersant is monoethanolamine.

In some embodiments, the compositions of the invention further comprise a wetting agent. Suitable wetting agents are chosen from polymers and surfactants.

Exemplary polymers include, but are not limited to, acrylic or methacrylic acid homopolymer and copolymers and salts thereof, for example, acrylamidomethylpropane sulfonic acid and maleic acid; poly AMPS (acrylamido-2-methyl-1-propane sulfonic acid), poly(vinyl sulfonic acid), poly(acrylic acid-co-styrene), poly(hydroxyethyl)acrylate, poly(hydroxyethyl)methacrylate, dimethylaminomethacrylate polymers and copolymers thereof, trimethylammonium methylmethacrylate polymers and copolymers thereof, poly(acrylamide), and poly(acrylic acid) (PAA) and poly(methacrylic acid) (PMAA), including the sodium and ammonium salts thereof, and. Other suitable polymers include maleic acid/vinyl ether copolymers, poly(maleic acid-co-methylvinyl ether), polyvinylpyrrolidone (PVP), poly(vinylpyrrolidone)/vinyl acetate, poly(vinyl acetate), homopolymers such as Poly(styrene-co-2-Acrylamido-2-methylpropane sulfonic acid), Poly(styrene-co-vinyl pyrrolidone), poly(styrene-co-allyl alcohol), poly(styrene-co-maleic anhydride), poly(maleic anhydride-co-2-Acrylamido-2-methylpropane sulfonic, phosphonated polyethyleneglycol oligomers, poly(ethylene glycol) (PEG), and poly(propylene glycol) (PPG), polyethylene oxide (PEO), PPG-PEG-PPG block copolymers, PEG-PPG-PEG block copolymers, hydroxyethyl cellulose, methylhydroxyethyl cellulose, hydroxypropyl cellulose, methylhydroxypropyl cellulose, xanthan gum, potassium alginate, pectin, carboxymethylcellulose, glucosamine, poly(diallyldimethylammonium) chloride, PEGylated (i.e., polyethyleneglycol-ated) methacrylate/acrylate copolymers, poly MADQuat and copolymers thereof, and poly(vinyl alcohol). Additional examples include poly(styrene sulfonic acid), poly(vinyl sulfonic acid), poly(vinyl phosphonic acid), and poly(vinyl phosphoric acid), as well as salts thereof as well as poly(ethyleneimine), poly(propyleneimine), polyallylamine, and salts thereof. Combinations of these polymers may also be used. The copolymers above may be random or block copolymers. When present, the amount of polymer(s) in the composition is in a range from about 0.0001 weight % to about 5 weight %, based on the total weight of the composition. In another embodiment the amount of polymer(s) in the composition is in the range from about 0.0001 weight % to about 5 weight %, based on the total weight of the composition.

As used herein the term “surfactant” refers to an organic compound that lowers the surface tension (or interfacial tension) between two liquids or between a liquid and a solid, typically an organic amphiphilic compound that contains a hydrophobic group (e.g., a hydrocarbon (e.g., alkyl) “tail”) and a hydrophilic group. Exemplary surfactants include, but are not limited to, amphoteric salts, cationic surfactants, anionic surfactants, zwitterionic surfactants, non-ionic surfactants, and combinations thereof including, but not limited to, decylphosphonic acid, dodecylphosphonic acid (DDPA), tetradecylphosphonic acid, hexadecylphosphonic acid, bis(2-ethylhexyl)phosphate, octadecylphosphonic acid, perfluoroheptanoic acid, prefluorodecanoic acid, trifluoromethanesulfonic acid, phosphonoacetic acid, dodecylbenzenesulfonic acid (DDBSA), 2,4,7,9-Tetramethyl-5-decyne-4,7-diol, mixture of (±) and meso, 2,4,7,9-Tetramethyl-5-decyne-4,7-diol ethoxylate benzene sulfonic acids or salts thereof, optionally substituted by one or more C₈-C₁₈ straight or branched-chain alkyl groups, dipehenyl oxides such as the Calfax series, dodecenylsuccinic acid, dioctadecyl hydrogen phosphate, octadecyl dihydrogen phosphate, dodecylamine, dodecenylsuccinic acid monodiethanol amide, lauric acid, palmitic acid, oleic acid, juniperic acid, 12-hydroxystearic acid, octadecylphosphonic acid (ODPA), dodecyl phosphate. Non-ionic surfactants contemplated include, but are not limited to, polyoxyethylene lauryl ether, dodecenylsuccinic acid monodiethanol amide, ethylenediamine tetrakis (ethoxylate-block-propoxylate) tetrol, polyethylene glycols, polypropylene glycols, polyethylene or polypropylene glycol ethers, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether, branched, Polyoxyethylene (40) nonylphenylether, branched, dinonylphenyl polyoxyethylene, nonylphenol alkoxylates, polyoxyethylene sorbitol hexaoleate, polyoxyethylene sorbitol tetraoleate, polyethylene glycol sorbitan monooleate, sorbitan monooleate, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazanes, silicone-polyether copolymers, and ethoxylated fluorosurfactants. Cationic surfactants contemplated include, but are not limited to, cetyl trimethylammonium bromide (CTAB), heptadecanefluorooctane sulfonic acid, tetraethylammonium, stearyl trimethylammonium chloride, 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, hexadecyltrimethylammonium p-toluenesulfonate, didodecyldimethylammonium bromide, di(hydrogenated tallow)dimethylammonium chloride, tetraheptylammonium bromide, tetrakis(decyl)ammonium bromide, and oxyphenonium bromide, guanidine hydrochloride (C(NH₂)₃Cl) or triflate salts such as tetrabutylammonium trifluoromethanesulfonate, dimethyldioctadecylammonium chloride, dimethyldihexadecylammonium bromide, di(hydrogenated tallow)dimethylammonium chloride, and polyoxyethylene (16) tallow ethylmonium ethosulfate. Anionic surfactants contemplated include, but are not limited to, poly(acrylic acid sodium salt), ammonium polyacrylate, sodium polyoxyethylene lauryl ether, sodium dihexylsulfosuccinate, sodium dodecyl sulfate, dioctylsulfosuccinate salt, 2-sulfosuccinate salts, 2,3-dimercapto-1-propanesulfonic acid salt, dicyclohexyl sulfosuccinate sodium salt, sodium 7-ethyl-2-methyl-4-undecyl sulfate, phosphate fluorosurfactants, fluorosurfactants, and polyacrylates. Zwitterionic surfactants include, but are not limited to, acetylenic diols or modified acetylenic diols, ethylene oxide alkylamines, N,N-dimethyldodecylamine N-oxide, sodium cocaminpropinate, 3-(N,N-dimethylmyristylammonio)propanesulfonate, and (3-(4-heptyl)phenyl-3-hydroxypropyl)dimethylammoniopropanesulfonate. In another embodiment the amount of surfactant(s) in the composition is in the range from about 0.0001 weight % to about 5 weight %, based on the total weight of the composition.

In certain embodiments, the wetting agent is chosen from poly(vinyl pyrrolidone), hydroxyethylcellulose, ethoxylated fatty alcohols, xanthan gums, carboxyalkylcelluloses, and hydroxypropyl celluloses, polystyrene sulfonic acid and salts thereof, poly(acrylic acid) and salts thereof, and poly(methacrylic acid), and salts thereof.

In the compositions of the invention, suitable pH adjustors include acids and/or bases.

Bases include, but are not limited to, potassium hydroxide, ammonium hydroxide (i.e., ammonia), and a tetraalkylammonium hydroxide compound having the formula NR⁴R⁵R⁶R⁷OH, wherein R⁴, R⁵, R⁶ and R⁷ may be the same as or different from one another and are selected from the group consisting of hydrogen, straight-chain or branched C₁-C₆ alkyl (e.g., methyl, ethyl, propyl, butyl, pentyl, and hexyl) groups, C₁-C₆ hydroxyalkyl (e.g., hydroxymethyl, hydroxyethyl, hydroxypropyl, hydroxybutyl, hydroxypentyl, and hydroxyhexyl) groups, and substituted or unsubstituted C₆-C₁₀ aryl groups (e.g., benzyl groups). Tetraalkylammonium hydroxides that are commercially available include tetramethylammonium hydroxide (TMAH), tetraethylammonium hydroxide (TEAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, ethyltrimethylammonium hydroxide, tris(2-hydroxyethyl)methyl ammonium hydroxide, diethyldimethylammonium hydroxide, and combinations thereof, may be used. Alternatively or in addition, the pH adjusting agent may be a quaternary base having the formula (PR⁸R⁹R¹⁰R¹¹)OH, wherein R⁸, R⁹, R¹⁰, and R¹¹ may be the same as or different from one another and are selected from the group consisting of hydrogen, straight-chain C₁-C₆ alkyl (e.g., methyl, ethyl, propyl, butyl, pentyl, and hexyl) groups, branched C₁-C₆ alkyl groups, C₁-C₆ hydroxyalkyl (e.g., hydroxymethyl, hydroxyethyl, hydroxypropyl, hydroxybutyl, hydroxypentyl, and hydroxyhexyl) groups, substituted C₆-C₁₀ aryl groups, unsubstituted C₆-C₁₀ aryl groups (e.g., benzyl groups), and any combination thereof, such as tetrabutylphosphonium hydroxide (TBPH), tetramethylphosphonium hydroxide, tetraethylphosphonium hydroxide, tetrapropylphosphonium hydroxide, benzyltriphenylphosphonium hydroxide, methyl triphenylphosphonium hydroxide, ethyl triphenylphosphonium hydroxide, N-propyl triphenylphosphonium hydroxide.

Acids include, but are not limited to, nitric acid, sulfuric acid, phosphoric acid, hydrochloric acid, hydrobromic acid, methanesulfonic acid, benzenesulfonic acid, p-toluenesulfonic acid, trifluoromethanesulfonic acid, acetic acid, lactic acid, glycolic acid, and any combination thereof.

In one embodiment, the pH adjusting agent is chosen from at least one of KOH and choline hydroxide.

In some embodiments, the compositions of the invention further comprise a fluoride compound. As used herein, “fluoride compound” corresponds to species having ionic fluoride ion (F—) or covalently bonded fluorine. It is to be appreciated that the fluoride species may be included as a fluoride species or generated in situ. In certain embodiments, this compound capable of generating the fluoride ion will be derived from HF, monoflurophosphoric (MFPA), difluorophosphoric (DFPA), or hexafluorophosphoric acid. In other embodiments, the fluoride compound may be chosen from CsF and KF. In other embodiments, the fluoride compound may be chosen from tetramethylammonium hexafluorophosphate; ammonium hexafluorophosphate; ammonium fluoride; ammonium bifluoride (NH₄HF₂); quaternary ammonium tetrafluoroborates and quaternary phosphonium tetrafluoroborates having the formula NR′₄BF₄ and PR′₄BF₄, respectively, wherein each R′ may be the same as or different from one another and is chosen from hydrogen, straight-chained, branched, or cyclic C₁-C₆ alkyl (e.g., methyl, ethyl, propyl, butyl, pentyl, hexyl), and straight-chained or branched C₆-C₁₀ aryl (e.g., benzyl); tetrabutylammonium tetrafluoroborate (TBA-BF₄); and combinations thereof. In certain embodiments, the fluoride compound is selected from ammonium fluoride, ammonium bifluoride, quaternary ammonium tetrafluoroborates (e.g., tetramethylammonium tetrafluoroborate, tetraethylammonium tetrafluoroborate, tetrapropylammonium tetrafluoroborate, tetrabutylammonium tetrafluoroborate), quaternary phosphonium tetrafluoroborates, or combinations thereof. In certain embodiments, the fluoride compound comprises ammonium bifluoride, ammonium fluoride, or a combination thereof.

In another embodiment, the composition further comprises a biocide. Exemplary biocides include 5-chloro-2-methyl-4-isothiazolin-3-one, 2-methyl-4-isothiazolin-3-one, benzisothiazolone, 1, 2-benzisothiazol-3[2H]-one, methylisothiazolinone, methylchloroisothiazolinone, and combinations thereof.

As used herein, the term “residue” (which is inclusive of a “contaminant”) refers to any material that is a chemical or particulate material that remains present at a surface of a microelectronic device substrate after a processing step used in the fabrication of a microelectronic device, for example processing steps including plasma etching, plasma ashing (to remove photoresist from an etched wafer), chemical-mechanical processing, wet etching, etc. The residue may be any non-aqueous chemical material that is part of a processing composition used in the processing step, such as a chemical etchant, a photoresist, a CMP slurry, etc. The residue may alternately be a substance that is derived from a material of the processing composition during a processing step. Examples of these types of residues include non-aqueous, particulate or non-particulate, chemical or abrasive materials (e.g., abrasive particles, surfactant, oxidizer, corrosion inhibitor, catalyst) that remain at a surface of the substrate after processing. The residue may be originally present in a material such as a CMP slurry or an etching composition, such as a solid abrasive particle or chemical material present in a CMP abrasive slurry. Alternately, a residue may be a by-product or a reaction product (in particulate (e.g., agglomerate, precipitate) or non-particulate form) that is generated during processing, e.g., a by-product or reaction product of a chemical present in a processing composition such as CMP slurry or wet etching composition, or a chemical that is present, used during, or produced during a plasma etching or a plasma ashing process.

The term “post-CMP residue” refers to residue that is present at an end of a CMP processing step, for example a particle or chemical material that is present in or derived from a CMP slurry; specific examples include abrasive particles (e.g., silica-containing or silica-based abrasive particles, metal oxide (e.g., alumina) particles, ceria or ceria-based particles and the like); chemicals that are originally present in the slurry such as an oxidizer, catalyst, surfactant, inhibitor, complexing agent, etc.; a metal (e.g., ion), metal oxide, or metal complex that is derived from a metal material removed from the substrate surface being processed; or a reaction product or complex produced using a chemical of the slurry with another chemical of the slurry or with a chemical material derived from the substrate, such as a metal ion; pad particles; or any other material that is a product of the CMP process.

A “post-etch residue” refers to a material remaining following a gas-phase plasma etching process, e.g., back-end-of-line (“BEOL”) dual damascene processing, or wet etching processes. A post-etch residue may be organic, organometallic, organosilicic, or inorganic in nature, for example, silicon-containing material, carbon-based organic material, and etch gas residues such as oxygen and fluorine.

A “post-ash residue” refers to material remaining following oxidative or reductive plasma ashing to remove hardened photoresist and/or bottom anti-reflective coating (BARC) materials. The post-ash residue may be organic, organometallic, organosilicic, or inorganic in nature.

As noted above, the present invention relates to compositions (i.e., cleaning compositions) that are useful in a cleaning method that removes residue from a surface of a microelectronic device substrate that has residue thereon. Described compositions are compositions that contain an aqueous carrier (i.e., water) along with a combination of non-aqueous ingredients as set forth herein. In certain embodiments, the compositions, before being used in a cleaning process, are homogeneous solutions that comprise, consist of, or consist essentially of water and dissolved non-aqueous ingredients, in the absence of any solid or suspended materials such as solid abrasive particles, agglomerates, coagulates, etc.

A composition as described is useful for cleaning microelectronic devices and precursors thereof, specifically including microelectronic device substrates, meaning semiconductor wafers that include on a surface one or more microelectronic devices or precursors thereof that are in the process of being fabricated into final, completed and functional microelectronic devices. As used herein, a microelectronic device is a device that includes electrical circuits and related structures of very small (e.g., micron-scale or smaller) dimensions formed thereon. Exemplary microelectronic devices include flat panel displays, integrated circuits, memory devices, solar panels, photovoltaics, and microelectromechanical systems (MEMS). A microelectronic device substrate is a structure such as a wafer (e.g., semiconductor wafer) that includes one or more microelectronic devices or precursors thereof, in a state of being prepared to form a final microelectronic device.

The compositions and methods described herein are useful to clean any of various forms of microelectronic devices, at any stage of processing. Microelectronic device substrates (or simply “substrates,” herein, for short) that can be cleaned with particular utility and benefit include substrates that include exposed cobalt, tungsten, or dielectrics, or all three, at a surface of the substrate.

Microelectronic device substrates that can be cleaned with particular utility and benefit include those substrates which include hydrophobic surfaces, such as those having exposed carbon or SiC surfaces. In certain cases, the inclusion of a wetting agent as set forth herein was found to be particularly advantageous when used to clean such device substrates.

According to the invention, the compositions can be used for cleaning these general and specific types of microelectronic device substrates to remove residues, such as but not limited to the post-CMP residue, post-ash residue, post-etch residue, or other residue present at a substrate surface following a step of processing a microelectronic device substrate. The cleaning compositions provide useful or advantageous cleaning properties, meaning that the cleaning compositions are capable of being used with known equipment (e.g., post-CMP cleaning equipment), to substantially reduce the amount of residue, contaminant, or both, at a surface of a microelectronic device substrate, with improved levels of adverse effects on such cobalt, tungsten, and dielectric surfaces. A high percentage of residue that is present at a substrate surface can be successfully removed from the surface by use of cleaning compositions and methods described herein, for example at least 70, 80, 85, 90, 95, or 99 percent of residue may be removed (also referred to as “cleaning efficiency”).

Methods and equipment for measuring residue at a surface of a microelectronic device substrate are well known. Cleaning efficacy may be rated based on a reduction of an amount (e.g., number) of residue particles present on a microelectronic device surface after cleaning, compared to the amount (e.g., number) of residue particles present before cleaning. For example, pre- and post-cleaning analysis may be carried out using an atomic force microscope. Residue particles on a surface may be registered as a range of pixels. A histogram (e.g., a Sigma Scan Pro) may be applied to filter the pixels in a certain intensity, e.g., 231-235, and the number of residue particles counted. The amount of residue particle removal, i.e., cleaning efficiency, may be calculated using the ratio:

### (Number of PreClean Residue Particles on a Surface-Number of PostClean Residue Particles on the Surface): (Number of PreClean Residue Particles on the Surface).

Alternately, cleaning efficacy may be considered as a percentage of a total amount of a substrate surface that is covered by residue particulate matter before as compared to after cleaning. For example, an atomic force microscope may be programmed to perform a z-plane scan to identify topographic areas of interest above a certain height threshold, and then calculate the area of the total surface covered by the areas of interest. A reduced amount of area determined to be areas of interest, after cleaning, indicates a more efficacious cleaning composition and cleaning process.

The compositions of the invention can be prepared and then sold in the form a concentrate, which contains water at a relatively low amount, and, consequently, a relatively concentrated amount of non-aqueous ingredients. The concentrate is prepared commercially to be sold and transported while containing the concentrated amount of non-aqueous ingredients and relatively reduced amount of water, and to be eventually diluted by a purchaser of the concentrate at a point of use. The amounts of the different non-aqueous ingredients in the concentrate are amounts that, upon dilution of the concentrate, will result in desired amounts of those non-aqueous ingredients being present in the use composition.

The composition as described includes water as a liquid carrier, i.e., solute, of the non-aqueous ingredients. The water can be deionized (DIW) water. Water can be present in the composition from any source, such as by being contained in an ingredient that is combined with other ingredients to produce a composition in the form of a concentrate; or as water combined in pure form to other ingredients of a concentrate; or as water added to a concentrate by a user, e.g., at a point of use, as dilution water for the purpose of diluting the concentrate to form a use composition.

The amount of water in a composition can be a desired amount for a concentrate, or a desired amount of a use composition, which is generally a higher total amount relative to the amount of water in a concentrate. Exemplary amounts of water in a concentrate composition, not to be considered limiting, may be from about 30, 40, or 50 to about 85 or 90 weight percent, e.g., from about 60, 65, or 70 to about 80 weight percent water, based on total weight of a concentrate composition. Upon dilution, these amounts will be reduced by a factor of the dilution.

The composition of the invention can be easily prepared by simple addition of the respective ingredients and mixing to homogeneous condition, such as a solution. Furthermore, a composition may be readily formulated as single-package formulations or multi-part formulations that are mixed at or before the point of use, e.g., the individual parts of the multi-part formulation may be mixed by a user either at a processing tool (cleaning apparatus) or in a storage tank upstream of the processing tool.

Accordingly, another aspect of the invention relates to a kit including, in one or more containers, one or more components of the composition as set forth herein. The kit may include, in one or more containers, the components of the compositions as set forth herein, for combining with additional solvent (e.g., water) at the fab or the point of use. The kit may also include the other optional ingredients recited herein. The containers of the kit must be suitable for storing and shipping the compositions and may be, for example, NOWPak® containers (Entegris, Inc., Billerica, Mass., USA).

Additionally, a composition as described herein may be provided commercially for sale in the form of a concentrate that can be diluted with an appropriate amount of water at a point of use. In a concentrate form, the composition (concentrate) includes non-aqueous ingredients as set forth herein that will be present in the concentrate in amounts such that when the concentrate is diluted with a desired amount of water (e.g., DI water) each component of the cleaning composition will be present in the diluted use composition in an amount that is desired for use in a cleaning step such as a post-CMP cleaning step. The amount of water added to the concentrate to form the use composition may be one or multiple volumes of water per volume of the concentrate, for example 2 volumes of water (e.g., 3, 4, 5, or 10 volumes of water) per volume of the concentrate. When the concentrate is diluted with such an amount of water, each of the solid components of the concentration will be present in the use composition in a concentration that is reduced based on the number of volumes of water added to dilute the concentrate.

A cleaning composition as described can be useful in microelectronic device processing applications that include processes for cleaning a substrate surface by a method such as post-etch residue removal, post-ash residue removal surface preparation, post-CMP residue removal, and the like. Example substrates that may be cleaned by such a process include substrates that include metallic tungsten, metallic cobalt, low-k dielectric material, or all three, in the presence of at least one surface comprising hydrophobic carbon or SiC.

A cleaning composition and cleaning method are effective to remove a substantial amount of residue from the surface, of an amount that is initially present at the surface before the cleaning step. In one embodiment, the cleaning composition can be effective, in a cleaning step, to remove at least 85 percent of residue present on a surface of the substrate prior to residue removal by a cleaning step, or at least 90 of residue, or at least 95 percent of residue, or at least 99 percent of residue initially present before the cleaning step.

In a cleaning step, such as a post-CMP residue cleaning step, a cleaning composition may be used with any of a variety of known, conventional, commercially available cleaning tools such as megasonics and brush scrubbing, including, but not limited to, Verteq single wafer megasonic Goldfinger, OnTrak systems DDS (double-sided scrubbers), SEZ or other single wafer spray rinse, Applied Materials Mirra-Mesa™/Reflexion™/Reflexion LK™, and Megasonic batch wet bench systems, and Ebara Technologies, Inc. products such as 300 mm models (FREX300S2 and FREX300X3SC) and the 200 mm CMP system (FREX200M).

Conditions and timing of a cleaning step can be as desired, and may vary depending on the type of substrate and residue. In use of a composition for cleaning post-CMP residue, post-etch residue, post-ash residue or contaminants from a microelectronic device substrate having same thereon, the cleaning composition may be contacted with the substrate surface for a time of from about 1 second to about 20 minutes, e.g., from about 5 second to 10 minutes, or from about 15 sec to about 5 minutes, at temperature in a range of from about 20° C. to about 90° C., or about 20° C. to about 50° C. Such contacting times and temperatures are illustrative, and any other suitable time and temperature conditions may be useful if efficacious to at least partially, preferably substantially, clean an initial amount of residue from a surface.

Following desired level of cleaning of a device substrate surface, the cleaning compositions used in a cleaning step may be readily removed from the device surface, as may be desired and efficacious in a given end use application. For example, removal may be performed by use of a rinse solution that includes deionized water. Thereafter, the device may be processed as desired, such as by being dried (e.g., using nitrogen or a spin-dry cycle), followed by subsequent processing of the cleaned and dried device surface.

In other more general or specific methods, a microelectronic device substrate may first be subjected to processing step that includes by any one or more of CMP processing, plasma etching, wet etching, plasma ashing, or the like, followed by a cleaning step that includes cleaning the substrate surface with the composition of the present invention. At the end of the first processing step, residue (e.g., post-etch residue, post-CMP residue, post ash residue, etc.) will be present at a surface of the substrate. The cleaning step, using a cleaning composition as described, will be effective to clean a substantial amount of the residue from the microelectronic device surface.

Accordingly, in a further aspect, the invention provides a method for removing residues from a microelectronic device substrate having said residues thereon, wherein the substrate possesses at least one hydrophobic surface, particularly a surface comprising hydrophobic carbon or SiC. The method comprises:

contacting the surface of a microelectronic device substrate with a composition comprising:
a. a chelating agent;
b. a water-miscible solvent;
c. a reducing agent; and
d. a pH adjustor,
   wherein the composition has a pH of about 2 to about 13; and at least partially removing said residues from said substrate.

### EXAMPLES

ICP-procedure

In a 50 mL metal-free tube, 30 gm of diluted 100× (or 60+) formulation was taken and added 0.1 gm of Fe₂O₃ into the formulation. A stir bar was placed and dialled at room temperature at 600 rpm for 5 min. Next, 1.8 ml of aliquot was transferred into a centrifuge tube and centrifuge for 20 min at 15,000 rpm. The tube was removed from the centrifuge and transferred supernatant into a 15 mL metal-free ICP tube. Prepare a 1-to-100 diluted sample for ICP analysis by pipetting 0.1 mL of supernatant into a metal-free 15-mL tube containing 9.9 mL 2% Nitric Acid. Vortex ICP sample(s) to thoroughly mix. Place samples into Autosampler rack to await iron (Fe) ICP-OES Analysis. Determine iron (Fe) content by single element ICP-OES iron (Fe) Analysis.

| | | | | | | | | | | | Dissolved | |
|---|---|---|---|---|---|---|---|---|---|---|---|---|
| | | HEDP | | | PVP | | NH₄HF₂ | | Choline | | Fe | |
| Ex. | H₂O | (60%) | MEA | TGMBE | (30%) | DEHA | (32%) | KOH | hydroxide | pH | [ppb] | Comments |
| C* | yes | 1.36 | 2.5 | — | 2.67 | — | — | yes | — | 13.8 | 1563 | low Fe- |
| | | | | | | | | | | | | dissolution at |
| | | | | | | | | | | | | high pH |
| 1 | yes | 5 | 2.5 | 2.5 | 2.67 | 1 | — | — | | 2.5 | 5280 | lower pH |
| 2 | yes | 5 | 2.5 | 2.5 | 2.67 | 1 | | | | 2 | 8022 | improves Fe- |
| 3 | yes | 5 | 2.5 | 2.5 | 2.67 | 1 | — | — | — | 1.5 | 8575 | dissolution |
| 4 | yes | — | 2.5 | 2.5 | 2.67 | 1 | — | — | | 2.5 | 3452 | no chelating |
| | | | | | | | | | | | | reagent |
| | | | | | | | | | | | | reduces Fe- |
| | | | | | | | | | | | | dissolution |
| | | | | | | | | | | | | efficiency |
| 5 | yes | 5 | 2.5 | 2.5 | 2.67 | 1 | 2.92 | — | — | 4 | 7985 | etchant has |
| | | | | | | | | | | | | marginal |
| | | | | | | | | | | | | impact on Fe- |
| | | | | | | | | | | | | dissolution |
| 6 | yes | 5 | 2.5 | 2.5 | 2.67 | — | — | — | — | 2.5 | 6289 | reducing agent |
| | | | | | | | | | | | | enhances Fe- |
| | | | | | | | | | | | | dissolution |

*Comparative Example Composition

Procedure: Place the first 1″×1″ coupon to be measured on the Contact Angle “stage”—note that the “Control” coupon (no etching) should be measured first. Slide the coupon under the needle. Bring the stage to a point. Bring the Needle down. Make Drop to release a drop of DIW from the Contact Angle instrument.

TABLE 2
Contact Angle Performance

| Formulation | 1 | 2 | 3 | 4 | 5 | 6 | 7 | 8 | 9 |
|---|---|---|---|---|---|---|---|---|---|
| DIW (H₂O) | 15.8 | 11.5 | 15.5 | 14.6 | 14.6 | 14.6 | 14.6 | 15.2 | 15.2 |
| TGMBE | 8.4 | 8.4 | 8.4 | 8.4 | 8.4 | 8.4 | 8.4 | 8.4 | 8.4 |
| MEA | 8.4 | 8.4 | 8.4 | 8.4 | 8.4 | 8.4 | 8.4 | 8.4 | 8.4 |
| HEDP | 16.7 | 16.7 | 16.7 | 16.7 | 16.7 | 16.7 | 16.7 | 16.7 | 16.7 |
| DEHA | 8.4 | 8.4 | 8.4 | 8.4 | 8.4 | 8.4 | 8.4 | 8.4 | 8.4 |
| ammonium | 1.6 | 1.6 | 1.6 | 1.6 | 1.6 | 1.6 | 1.6 | 1.6 | 1.6 |
| bifluoride | | | | | | | | | |
| PVP (30%) | — | 4.3 | — | — | — | — | — | — | — |
| [5102] | | | | | | | | | |
| HEC (solid add | — | — | 0.3 | — | — | — | — | — | — |
| fine) | | | | | | | | | |
| Brij L23 * | — | — | — | 1.2 | — | — | — | — | — |
| Pluronic 17R4 ** | — | — | — | — | 1.2 | — | — | — | — |
| Surfynol 104 | — | — | — | — | — | 1.2 | — | — | — |
| Surfactant | | | | | | | | | |
| Span ® 80 *** | — | — | — | — | — | — | 1.2 | — | — |
| Xanthan gum | — | — | — | — | — | — | — | 0.6 | — |
| polyvinyl alcohol | — | — | — | — | — | — | — | — | 0.6 |
| HNO₃ (30%) | 40.9 | 40.9 | 40.9 | 40.9 | 40.9 | 40.9 | 40.9 | 40.9 | 40.9 |
| pH | 2.2 | 2.2 | 2.2 | 2.2 | 2.2 | 2.2 | 2.2 | 2.2 | 2.2 |
| Mean Contact | 57.5 | 41.5 | 50.6 | 55.2 | 63.6 | 62.8 | 61.0 | 38.3 | 58.1 |
| Angle (θ) | | | | | | | | | |
| Std. Dev. | 1.7 | 1.5 | 0.8 | 1.6 | 1.6 | 1.1 | 1.2 | 2.2 | 0.5 |

** For those compositions which were acidic, HNO₃ was added to adjust pH.
* Brij L23 = polyoxyethylene(23)lauryl ether
** Pluronic 17R4 surfactant (BASF)
*** Span ® 80, sorbitan monooleate (Croda)

TABLE 3
TOF-SIMS metal analysis on silicon oxide films polished with
KMnO₄/Zr based slurry and cleaned with Formulations 1-8:

| | | | | | | | | | | Reducing | | TOF-SIMS, | |
|---|---|---|---|---|---|---|---|---|---|---|---|---|---|
| | Citric | | | | | | | | | agents | | counts | |
| Ex. | Acid | HEDP | DMSO | BzOH | MSA | AA | OA | TGMBE | PVP | H₂O₂ | DEHA | Mn | Zr |
| C* | 0.85 | | | | | | | | | 3 | | 24708 | 4402 |
| 7 | | 0.2 | 0.15 | | | | | | | 3 | | 12540 | 208 |
| 8 | | 0.2 | 0.15 | | | | 0.1 | | | 3 | | 10425 | 175 |
| 9 | 0.85 | | | 0.5 | | | | | | 3 | | 18540 | 560 |
| 10 | | | | | 0.5 | | | | | 3 | | 16205 | 703 |
| 11 | | | | | | 0.5 | | | | 3 | | 17340 | 820 |
| 12 | | 0.2 | | | | | | 2.5 | 0.1 | | 3 | 13720 | 462 |
| 13 | 0.85 | | | 0.5 | | | 0.1 | | | 3 | | 13259 | 254 |
| 14 | | 0.2 | 0.15 | | | | | | 0.2 | 3 | | 11793 | 238 |

*All ingredients are in weight percent
Legend:
DMSO = dimethylsulfoxide
BzOH = benzyl alcohol
MSA = methane sulfonic acid
AA = acetic acid
OA = oxalic acid
TGMBE = triethylene glycol monobutyl ether
PVP = polyvinyl pyrrolidone

The improvement in metals removal with the Example 7 through 14 formulations vs. control is: 1.33×-2.4× less surface Mn and 5.36×-25.15× less surface Zr. The same formulations 7-4 used to clean hydrophobic carbon films had similar improved performances vs. Control, 2×-4.3× less surface Mn and 16×-28× less surface Zr (TOF-SIMS data).

TABLE 4
Turbidity
Base Formulation

| Component | Final Spec. (%) |
|---|---|
| MEA | 8.35 |
| HEDP | 10.02 |
| DEHA | 8.35 |
| Ammonium bifluoride | 0.50 |
| Nitric acid (HNO₃) | 12.26 |

The compositions of Examples A-H in the table below contain the amounts of solvent and polymer shown in the table below with the balance being the following base formulation:

Turbidity values were determined by adding 0.02 g of 10 nm diamonds to the formulations, which was pre-diluted by adding 0.3 g of the concentrated formulation to 29.7 g of DI water, then immersed in an ultrasonic bath for 5 minutes, and then rotated in a synchronized rotator for 5 minutes. The turbidity was recorded vs. time. The values in the table are for turbidity measured 8 minutes after ultrasonic treatment. Higher turbidity after 8 minutes means that the diamonds are better dispersed and/or settling slower.

| Ex | | Solvent | Polymer | Turbidity |
|---|---|---|---|---|
| A | Base | 8.35% trimethylene glycol | none | 2037 |
| | Formulation + | monobutyl ether | | |
| B | Base | 8.35% trimethylene glycol | 1.34% polyvinyl(pyrrolidone) | 2607 |
| | Formulation + | monobutyl ether | | |
| C | Base | 8.35% trimethylene glycol | 1.34% poly(styrene sulfonic acid) | 3816 |
| | Formulation + | monobutyl ether | | |
| D | Base | 8.35% dimethyl sulfoxide | 1.34% polyvinyl(pyrrolidone) | 1356 |
| | Formulation + | | | |
| E | Base | 8.35% dimethyl sulfoxide | 1.34% poly(styrene sulfonic acid) | 3924 |
| | Formulation + | | | |
| F | Base | 8.35% dimethyl sulfoxide | 1.34% poly(methacrylic acid), | 3615 |
| | Formulation + | | ammonium salt | |
| G | Base | 8.35% dimethyl sulfoxide | 1.34% poly(styrene sulfonic acid) + | 4522 |
| | Formulation + | | 0.1% hydroxyethyl cellulose | |
| H | Base | 8.35% dimethyl sulfoxide | 1.34% hydroxyethyl cellulose | 606 |
| | Formulation + | | | |

### Aspects

In a first aspect, the invention provides a composition comprising:
a. chelating agent;
b. a water-miscible solvent;
c. a reducing agent; and
d. a pH adjustor,
   wherein the composition has a pH of about 1.5 to about 13.

In a second aspect, the invention provides the composition of the first aspect, wherein the pH is about 1.5 to about 5.

In a third aspect, the invention provides the composition of the first or second aspect, wherein the composition further comprises a dispersant.

In a fourth aspect, the invention provides the composition of any one of the first, second, or third aspects, wherein the composition further comprises a wetting agent.

In a fifth aspect, the invention provides the composition of any one of the first through the fourth aspects, wherein the composition further comprises a fluoride source.

In a sixth aspect, the invention provides the composition of the first aspect, comprising:
a. a chelating agent chosen from 1-hydroxyethylidene-1,1-diphosphonic acid; nitrilotris(methylene)triphosphonic acid, and citric acid;
b. a water-miscible solvent chosen from triethylene glycol monobutyl ether, dimethylsulfoxide, and diethylene glycol monobutyl ether;
c. a reducing agent chosen from diethylhydroxylamine and hydrogen peroxide;
d. a pH adjustor chosen from choline hydroxide, potassium hydroxide, nitric acid, methanesulfonic acid, and sulfuric acid.

In a seventh aspect, the invention provides the composition of the sixth aspect, further comprising a wetting agent.

In an eighth aspect, the invention provides the composition of the sixth or seventh aspects, wherein the pH is about 1.5 to about 4.

In a ninth aspect, the invention provides the composition of any one of the sixth, seventh, or eighth aspects, wherein the water-miscible solvent comprises dimethylsulfoxide.

In a tenth aspect, the invention provides the composition of the first aspect, comprising:
a. a dispersant chosen from monoethanolamine, triethanolamine, and tris(hydroxymethyl)aminomethane;
b. a chelating agent chosen from hydroxyethylidene diphosphonic acid; nitrilotris(methylene)phosphonic acid and citric acid;
c. a water-miscible solvent chosen from triethylene glycol monobutyl ether, dimethylsulfoxide, and diethylene glycol monobutyl ether; and
d. a wetting agent chosen from polyvinylpyrrolidone, hydroxyethylcellulose, ethoxylated C₈-C₁₈ alcohols, polystyrene sulfonic acid and salts thereof, poly(acrylic acid) and salts thereof, and poly(methacrylic acid), and salts thereof; and
e. a pH adjustor chosen from nitric acid, choline hydroxide, and KOH; and
   wherein the pH is about 2 to about 5.

In an eleventh aspect, the invention provides the composition of the first or tenth aspects, comprising:
f. monoethanolamine;
g. hydroxyethylidene diphosphonic acid;
h. triethylene glycol monobutyl ether;
i. polyvinyl pyrrolidone; and
j. nitric acid.

In a twelfth aspect, the invention provides the composition of the tenth or eleventh aspect, further comprising a fluoride source.

In a thirteenth aspect, the invention provides the composition of the twelfth aspect, wherein the fluoride source is ammonium bifluoride.

In a fourteenth aspect, the invention provides the composition of the tenth aspect, comprising:
k. monoethanolamine;
1. hydroxyethylidene diphosphonic acid;
m. triethylene glycol monobutyl ether;
n. hydroxyethyl cellulose;
o. nitric acid; and optionally
p. ammonium bifluoride.

In a fifteenth aspect, the invention provides the composition of the tenth aspect, comprising:
q. monoethanolamine;
r. hydroxyethylidene diphosphonic acid;
s. triethylene glycol monobutyl ether;
t. polyoxyethylene(23)lauryl ether;
u. nitric acid; and optionally
v. ammonium bifluoride.

In a sixteenth aspect, the invention provides a method for removing residues from a microelectronic device substrate having said residues thereon, wherein the substrate possesses at least one surface comprising hydrophobic carbon or SiC, the method comprising:

contacting the surface of a microelectronic device substrate with the composition of any one of the first through the sixteenth aspects; and at least partially removing said residues from said substrate.

In a seventeenth aspect, the invention provides a kit comprising one or more containers having components therein suitable for cleaning a microelectronic device, wherein one or more containers of said kit contains two or more components of the composition of any one of the first through the sixteenth aspects.

In an eighteenth aspect, the invention provides a composition of the invention provides a composition of the fourth aspect, wherein the wetting agent is chosen from poly(vinyl pyrrolidone), hydroxyethylcellulose, ethoxylated fatty alcohols, xanthan gums, carboxyalkylcelluloses, and hydroxypropyl celluloses, polystyrene sulfonic acid and salts thereof, poly(acrylic acid) and salts thereof, and poly(methacrylic acid), and salts thereof.

In a nineteenth aspect, the invention provides a composition of the fourth or eighteenth aspects, wherein the wetting agent is chosen from polystyrene sulfonic acid and salts thereof, poly(acrylic acid) and salts thereof, and poly(methacrylic acid), and salts thereof.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A composition comprising:
a. a chelating agent;
b. a water-miscible solvent;
c. a reducing agent; and
d. a pH adjustor,
wherein the composition has a pH of about 1.5 to about 13.

2. The composition of claim 1, wherein the pH is about 1.5 to about 5.

3. The composition of claim 1, wherein the composition further comprises a dispersant.

4. The composition of claim 1, wherein the composition further comprises a wetting agent.

5. The composition of claim 1, wherein the composition further comprises a fluoride source.

6. The composition of claim 1, comprising:
a. a chelating agent chosen from 1-hydroxyethylidene-1,1-diphosphonic acid; nitrilotris(methylene)triphosphonic acid, and citric acid;
b. a water-miscible solvent chosen from triethylene glycol monobutyl ether, dimethylsulfoxide, and diethylene glycol monobutyl ether;
c. a reducing agent chosen from diethylhydroxylamine and hydrogen peroxide;
d. a pH adjustor chosen from choline hydroxide, potassium hydroxide, nitric acid, methanesulfonic acid, and sulfuric acid.

7. The composition of claim 6, further comprising a wetting agent.

8. The composition of claim 6, wherein the pH is about 1.5 to about 4.

9. The composition of claim 6, wherein the water-miscible solvent comprises dimethylsulfoxide.

10. The composition of claim 1, comprising:
a. a dispersant chosen from monoethanolamine, triethanolamine, and tris(hydroxymethyl)aminomethane;
b. a chelating agent chosen from hydroxyethylidene diphosphonic acid; nitrilotris(methylene)phosphonic acid and citric acid;
c. a water-miscible solvent chosen from triethylene glycol monobutyl ether, dimethylsulfoxide, and diethylene glycol monobutyl ether; and
d. a wetting agent chosen from polyvinylpyrrolidone, hydroxyethylcellulose, ethoxylated C₈-C₁₈ alcohols, polystyrene sulfonic acid and salts thereof, poly(acrylic acid) and salts thereof, and poly(methacrylic acid), and salts thereof; and
e. a pH adjustor chosen from nitric acid, choline hydroxide, and KOH; and
wherein the pH is about 2 to about 5.

11. The composition of claim 10 comprising:
a. monoethanolamine;
b. hydroxyethylidene diphosphonic acid;
c. triethylene glycol monobutyl ether;
d. polyvinyl pyrrolidone; and
e. nitric acid.

12. The composition of claim 11, further comprising a fluoride source.

13. The composition of claim 12, wherein the fluoride source is ammonium bifluoride.

14. The composition of claim 10, comprising:
a. monoethanolamine;
b. hydroxyethylidene diphosphonic acid;
c. triethylene glycol monobutyl ether;
d. hydroxyethyl cellulose;
e. nitric acid; and optionally
f. ammonium bifluoride.

15. The composition of claim 10, comprising:
a. monoethanolamine;
b. hydroxyethylidene diphosphonic acid;
c. triethylene glycol monobutyl ether;
d. polyoxyethylene(23)lauryl ether;
e. nitric acid; and optionally
f. ammonium bifluoride.

16. A method for removing residues from a microelectronic device substrate having said residues thereon, wherein the substrate possesses at least one surface comprising a substance chosen from copper, cobalt, tungsten, or a dielectric composition along with at least one surface comprising hydrophobic carbon or SiC,
contacting the surface of a microelectronic device substrate with a composition comprising:
a. a chelating agent;
b. a water-miscible solvent;
c. a reducing agent; and
d. a pH adjustor,
wherein the composition has a pH of about 2 to about 13; and at least partially removing said residues from said substrate.

17. A kit comprising one or more containers having components therein suitable for cleaning a microelectronic device, wherein one or more containers of said kit contains two or more components of the composition of claim 1.

18. The composition of claim 4, wherein the wetting agent is chosen from poly(vinyl pyrrolidone), hydroxyethylcellulose, ethoxylated fatty alcohols, xanthan gums, carboxyalkylcelluloses, and hydroxypropyl celluloses, polystyrene sulfonic acid and salts thereof, poly(acrylic acid) and salts thereof, and poly(methacrylic acid), and salts thereof.

19. The composition of claim 18, wherein the wetting agent is chosen from polystyrene sulfonic acid and salts thereof, poly(acrylic acid) and salts thereof, and poly(methacrylic acid), and salts thereof.
